(19) United States
(12) Patent Application Publication
(10) Pub. No.: US 2012/0273951 A1
(43) Pub. Date: Nov. 1, 2012

(54) Contact Metal for Hybridization and Related Methods

(75) Inventors: Jonathan Getty, Goleta, CA (US); Andreas Hampp, Santa Barbara, CA (US); Aaron M. Ramirez, Santa Barbara, CA (US); Scott S. Miller, Buellton, CA (US)

(73) Assignee: RAYTHEON COMPANY, Waltham, MA (US)

(21) Appl. No.: 13/231,675

(22) Filed: Sep. 13, 2011

Related U.S. Application Data
(60) Provisional application No. 61/480,276, filed on Apr. 28, 2011.

(51) Int. Cl. H01L 23/532; H01L 21/60

(52) U.S. Cl. 257/751; 438/107; 257/E23.155; 257/E21.507

(57) ABSTRACT

A contact structure for interconnecting a first substrate to an indium interconnect structure on a second substrate. The contact structure comprises a diffusive layer and a non-oxidizing layer, with a thickness of less than approximately 150 nm, positioned on the diffusive layer for alignment with the indium interconnect.

This application claims the priority under 35 U.S.C. §119 of provisional application No. 61/480,276 filed Apr. 28, 2011, the entire contents of which are incorporated herein.

### BACKGROUND

Flip chip hybridization is a microelectronics packaging and assembly process which directly connects an individual chip to a substrate, eliminating the need for peripheral wirebonding. Electrical connections are made between the two parts using interconnect bumps consisting of a conductive material. One type of conductive interconnect bump that may be used for direct connection of certain active devices to the substrate is an indium bump. Traditional double-sided indium bump hybridization involves forming indium bumps on both the individual chip and the substrate. This double-sided technique results in additional processing, which may cause yield loss, added cost, and outsourcing difficulties. Conventional indium interconnect techniques may also complicate hybridization when used in dense interconnection applications.

### BRIEF DESCRIPTION OF THE DRAWINGS

The accompanying drawings illustrate embodiments of the devices and methods disclosed herein and together with the description, serve to explain the principles of the present disclosure.

FIG. 1 is a schematic view of a semiconductor interconnect structure according to one embodiment of the disclosure.

FIG. 2 is a schematic view of a semiconductor interconnect structure according to another embodiment of the disclosure.

FIG. 3 is a schematic view of the semiconductor interconnect structure of FIG. 1 after a bonding process.

FIG. 4 is a flow chart describing a method of bonding semiconductor interconnect structures according to one embodiment of the disclosure.

FIG. 5 is a flow chart describing a method of bonding semiconductor interconnect structures according to another embodiment of the disclosure.

The following disclosure provides many different embodiments, or examples, for implementing different features of the invention. Specific examples of components and arrangements are described below to simplify the present disclosure. These are, of course, merely examples and are not intended to be limiting.

### DETAILED DESCRIPTION

This application claims the priority under 35 U.S.C. §119 of provisional application No. 61/480,276 filed Apr. 28, 2011, the entire contents of which are incorporated by reference herein.

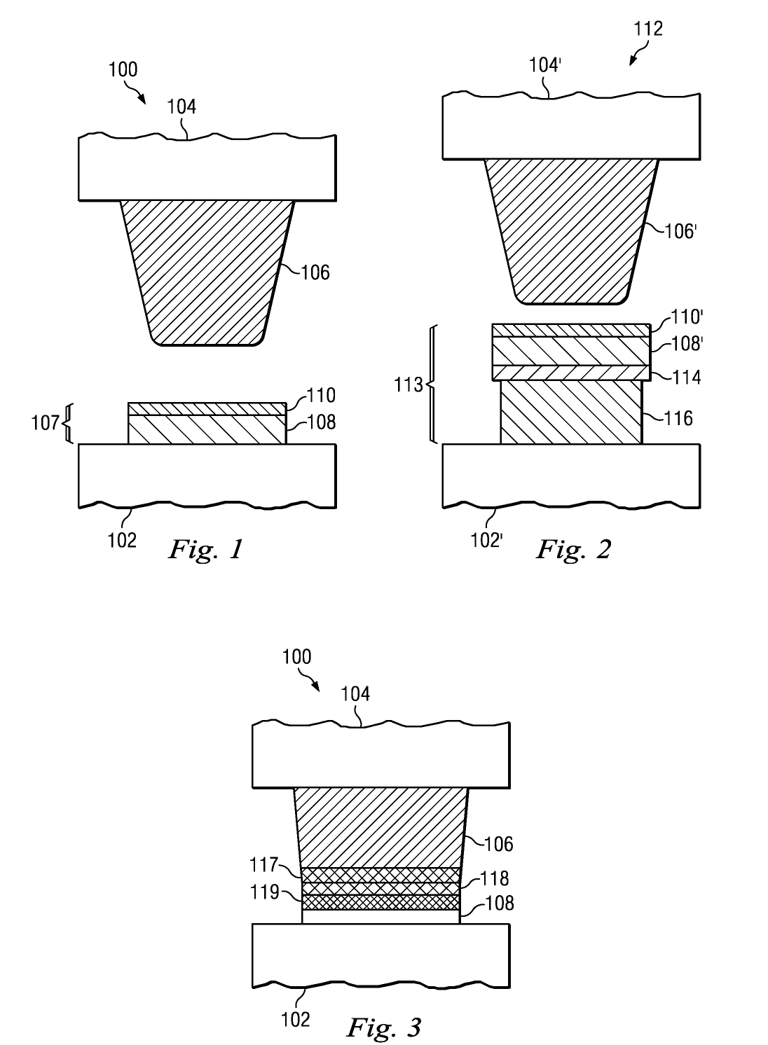

Referring first to FIG. 1, in one embodiment, a composite semiconductor structure 100 includes a integrated circuit chip 102 and an integrated circuit chip 104. The chips 102, 104 may be used, for example in sensor devices such as infrared detectors. In an exemplary embodiment, the chip 104 may be a substrate formed of one or more materials including, for example, silicon (Si), gallium arsenide (GaAs), indium phosphide (InP), or any other material suitable for forming a microelectronic circuit chip. In an exemplary embodiment, the chip 102 may be a photodetector formed of one or more materials including, for example, InP, indium gallium arsenide (InGaAs), mercury cadmium telluride (HgCdTe), indium antimonide (InSb), or other suitable photodetector material.

An interconnect structure 106 may be formed on the chip 104. In an exemplary embodiment, the interconnect structure 106 may be an indium (In) bump, but other suitable interconnect material such as tin (Sn) may be used. The indium bump 106 may extend from the surface of the chip 104 approximately 7-8 μm, although smaller or larger interconnect structures may be suitable. In this embodiment, the indium bump may be used without a capping layer of non-oxidizing or other metal material, however, in alternative embodiments, the use of a capping layer may be suitable.

To bond with the interconnect structure 106, a contact structure 107 may be formed on the chip 102. The contact structure 107 includes a diffusive layer 108 formed on the chip 102. The diffusive layer may be formed of one or more materials including nickel (Ni), silver (Ag), lead (Pb), Sn, or any other material suitable for soldering and robust mechanical and electrical bonding. In an exemplary embodiment, a diffusive layer formed of Ni having a thickness of approximately 200 nm may be used. The diffusive layer may be thicker or thinner depending upon the bonding properties needed for a particular application.

A non-oxidizing layer 110 may be formed on the diffusive layer 108. The non-oxidizing layer 110 may be formed of one or more materials including gold (Au), silver (Ag), palladium (Pd), platinum (Pt) or any other noble metal or other non-oxidizing or minimally oxidizing material. The layer 110 may be relatively thin compared to the indium bump 106. The non-oxidizing layer may serve as a “glue” layer that improves single-sided hybridization, removing the need for indium bump deposition and oxide-removal etches. In an exemplary embodiment, an Au layer has a thickness of approximately 10-200 nm. A layer thickness of approximately 15 nm, 50 nm, or 150 nm may be particularly suitable. This thin layer may bond strongly with the surface of the mating indium bump and diffuse well into the indium bump, without being thick enough to form brittle In-Au intermetallic compounds. Indium and gold, for example, are capable of diffusing into each other. Gold/indium systems display a very small about of solubility with indium may having an approximate 12% solubility in gold, and gold having an approximate 1% solubility in indium. With thin layers of non-oxidizing material, such as gold, the non-oxidizing material is able to reduce or prevent oxidation, but also diffuse into the indium to prevent the formation of intermetallic compounds.

The bump 106 and the layers 108, 110 may be formed using processes including chemical vapor deposition (CVD), plasma-enhanced CVD (PECVD), physical vapor deposition (PVD), atomic layer deposition (ALD), and/or other processes known in the art. The depicted portions of the semiconductor structure 100 are schematic only and are not intended to represent scale or relative size.

To connect the chip 102 to the chip 104, the interconnect structure 106 and the non-oxidizing layer 110 are aligned and bonded, thereby hybridizing the interconnect structure and the non-oxidizing layer. The bonding process may include the application of heat, pressure, ultrasonic energy, or other processes which promote the hybridization of the interconnect structure and the non-oxidizing layer. In the hybridization process, the diffusive layer may diffuse well into the indium bump and into the non-oxidizing layer. It may, for example, dissolve the non-oxidizing layer.

With prior art processes that bonded indium interconnect structures with relatively thick non-oxidizing structures, such as gold ball bumps, gold-indium intermetallic formations characterized by a pillowing or billowing effect known as “contact swells” were known to result. These brittle intermetallic formations could present, for example, a 4× volumetric increase. In the embodiments of this disclosure, these brittle intermetallic formations may be avoided. Specifically, the formation of intermetallic layers, such as AgIn₂ or AuIn₂ for example, may be avoided. With the use of a relatively thin layer of non-oxiding material, such as gold, compared to the larger indium interconnect structure, the non-oxidizing material may entirely or largely diffuse into either the indium interconnect structure, the diffusive layer, or both. Rather, more robust intermetallic formations of the interconnect material, e.g. In, and the diffusive material, e.g. Ni, may be formed. Using a hybridization structure and process according to the embodiments of this disclosure, brittle failures associated with the formation of indium/non-oxidizing material intermetallic formations may be avoided. The avoidance of brittle intermetallic formations may be more relevant for chip applications with temperatures ranging from room temperature to cryogenic temperatures (i.e. less than approximately −150° C. or 123 K) than for applications with high temperatures, such as lasers.

Referring to FIG. 2, in another embodiment, a composite semiconductor structure 112 includes a integrated circuit chip 102′, an integrated circuit chip 104′, an interconnect structure 106′, a diffusive layer 108′, and a non-oxidizing layer 110′ which may be essentially the same or substantially similar to the corresponding portions in the semiconductor structure 100. In this embodiment a contact structure 113 includes the diffusive layer 108′ and the non-oxidizing layer 110′. It further includes a barrier layer 114 which may serve to adhere to and block diffusion of the underlying material into the interconnect structure 106′. The barrier layer 114 may be formed, for example, from one or more materials including Pt, titanium tungsten (TiW), or other materials that provide a suitable barrier. In one particular embodiment, a TiW alloy with approximately 90% tungsten may be used. The barrier layer may be approximately 250-750 nm, with an approximately 500 nm thickness used in one particular embodiment. It would be understood by a person of ordinary skill in the art that other thicknesses may also be suitable.

The contact structure 113 may further include a contact portion 116 which serves as an interface between the chip 102′ and the barrier layer 114 or diffusive layer 108′. The contact portion 116 may be formed of one or more materials including Ti, Pt, Au, or gold-zinc (AuZn) alloy.

The depicted portions of the semiconductor structure 100 are schematic only and are not intended to represent scale or relative size.

To connect the chip 102′ to the chip 104′, the interconnect structure 106′ and the non-oxidizing layer 110′ are aligned and bonded, as described above, to thereby hybridize the interconnect structure and the non-oxidizing layer.

Referring now to FIG. 3 which is a schematic view of the embodiment of FIG. 1 following an alignment and bonding process as described. A bonded region 117 of the material of the interconnect structure 106 is formed that includes diffused atoms of at least a portion of the non-oxidizing material 110. The region 117 may have an approximately even disbursement of the non-oxidizing material within the interconnect material or may have a graded quality with the concentration of non-oxidizing material greatest near the region 118. The diffusion of the non-oxidizing material may serve to prevent the creation of brittle intermetallic formations in this region. A bonded region 118 is formed to include a mixture of atoms of the material of the interconnect structure 106 and the diffusive layer material 108. A bonded region 119 is formed to include the non-oxidizing material 110 and the diffusive layer material 108. The region 119 may have an approximately even disbursement of the non-oxidizing material or may have a graded quality with the concentration of non-oxidizing material greatest near the region 118. In some embodiments, one or more of the regions 117-119 may be omitted or altered.

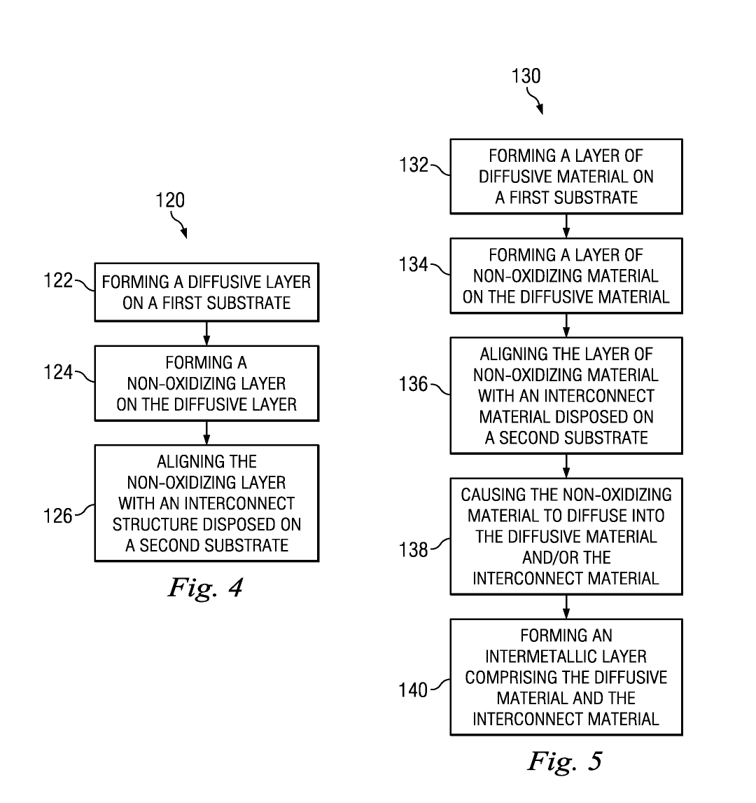

Referring now to FIG. 4, a method of forming and aligning a contact structure includes a step 122 of forming a diffusive layer on a first substrate, a step 124 of forming a non-oxidizing layer 124 on the diffusive layer, and a step 126 of aligning the non-oxidizing layer with an interconnect structure disposed on a second substrate.

Referring now to FIG. 5, in an alternative embodiment, a method 130 of forming an interconnect includes at step 132, forming a layer of a diffusive material, such as nickel or any of the diffusive layer materials listed above, on a first substrate. The method 130 further includes at step 134, forming a layer of non-oxidizing material, such as gold, silver, or any of the other non-oxidizing or minimally oxidizing materials listed above, on the diffusive material. The method 130 further includes at step 136, aligning the layer of non-oxidizing material with an interconnect material disposed on a second substrate. At step 138, the first substrate and the second substrate are bonded, causing the non-oxidizing material to diffuse into the diffusive material and/or the interconnect material. The diffusion of the entire layer non-oxidizing material may occur without the development of intermetallic formations comprising the non-oxidizing material and the interconnect material. As previously described, the bonding process may include the application of heat, pressure, ultrasonic energy, or other processes which promote the hybridization of the interconnect structures on each of the substrates. Optionally, at step 140, an intermetallic layer comprising the diffusive material and the interconnect material may be formed. Also optionally, oxide removal techniques may be used to remove or inhibit in situ oxide growth at the interconnecting structures.

The described contact structures may serve to form a strong bond on contact with the described interconnect structure. The described contact structures allow for hybridization without the need to remove oxide build up using an etching or other physical removal process. The described contact structures may not oxidize during hybridization, allowing lower force and improved contact during hybridization. The described contact structures are generally thinner and easier to deposit than conventional indium bumps or pads. The described contact structures can be deposited by InGaAs suppliers, allowing the outsourcing of some backend processing of wafers. The described contact structures leverage the thermodynamically favored dissolution of metals for bonding and electrical interconnects while avoiding alloying and the formation of brittle, binary indium-gold alloys.

These contact structures may be useful in dense interconnect technology. As compared to the relatively tall indium bumps formed by the prior art processes, the contacts formed with the processes disclosed herein may be thinner and more consistently deposited. The formation of the contact structures may be outsourced, for example, to detector suppliers.

The foregoing outlines features of selected embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure, as defined by the claims that follow.

What is claimed is:

1. A contact structure for interconnecting a first substrate to an indium interconnect structure on a second substrate, the contact structure comprising:
a diffusive layer and
a non-oxidizing layer with a thickness of less than approximately 200 nm positioned on the diffusive layer for alignment with the indium interconnect.

2. The contact structure of claim 1 wherein the diffusive layer includes Ni.

3. The contact structure of claim 1 wherein the non-oxidizing layer includes Au.

4. The contact structure of claim 1 wherein the non-oxidizing layer includes Ag.

5. The contact structure of claim 1 wherein the non-oxidizing layer has a thickness of less than approximately 100 nm.

6. The contact structure of claim 1 further including a barrier layer on which the diffusive layer is positioned.

7. A method of interconnecting a first substrate to an indium structure on a second substrate, the method comprising:
depositing a diffusive layer including a diffusive material;
depositing a non-oxidizing layer of less than approximately 200 nm, the layer including a non-oxidizing material;
positioning the non-oxidizing layer in alignment with the indium structure;
bonding the first and second substrate; and
form a first region including at least a portion of the non-oxidizing material dissolved in indium from the indium structure.

8. The method of claim 7 wherein the diffusive layer includes Ni.

9. The method of claim 7 wherein the non-oxidizing material includes Au.

10. The method of claim 7 wherein the non-oxidizing material includes Ag.

11. The method of claim 7 further comprising forming a second region including a mixture of the diffusive material and indium from the indium structure.

12. The method of claim 7 further comprising forming a barrier layer extending between the diffusive layer and the first substrate.

13. The method of claim 7 further comprising removing a native oxide from at least one of the first or second substrates.

14. A hybridized interconnect structure connecting first and second semiconductor substrates, the interconnect structure comprising:
a first region including a mixture of indium and a non-oxidizing material;
a second region including a mixture of indium and a diffusive material; and
a third region including a mixture of the non-oxidizing material and the diffusive material.

15. The hybridized interconnect structure of claim 14 wherein the non-oxidizing material includes gold.

16. They hybridized interconnect structure of claim 14 wherein the non-oxidizing material includes silver.

17. The hybridized interconnect structure of claim 14 wherein the diffusive material includes nickel.

18. The hybridized interconnect structure of claim 14 wherein the first region does not include brittle intermetallic formations.

19. The hybridized interconnect structure of claim 18 wherein the first region does not include brittle intermetallic formations when cooled to a cryogenic temperature.

20. The hybridized interconnect structure of claim 14 wherein the first region includes a graded distribution of non-oxidizing material within indium.
